(19) United States
(12) Patent Application Publication
(10) Pub. No.: US 2024/0178154 A1
(43) Pub. Date: May 30, 2024

(54) ELECTRONIC DEVICE PACKAGE EMI SHIELDING WITH GROUNDED MOLD INTERCONNECT

(71) Applicant: Texas Instruments Incorporated, Dallas, TX (US)

(72) Inventors: Yiqi Tang, Allen, TX (US); Rajen Manicon Murugan, Dallas, TX (US); Chittranjan Mohan Gupta, Richardson, TX (US); Jie Chen, Plano, TX (US); Jaimal Mallory Williamson, McKinney, TX (US)

(21) Appl. No.: 18/070,708

(22) Filed: Nov. 29, 2022

(51) Int. Cl. H01L 23/552; H01L 21/48; H01L 21/56; H01L 23/498

(52) U.S. Cl. CPC H01L 23/552; H01L 21/4853; H01L 21/56; H01L 23/49822; H01L 23/49838; H01L 24/16; H01L 2224/16227

(57) ABSTRACT

An electronic device includes a multilevel package substrate, a semiconductor die, and a molded package structure, where the multilevel package substrate has opposite first and second substrate sides, first and second conductive pads spaced apart from one another along the first substrate side, and a conductive substrate terminal that is exposed along the second substrate side and is electrically coupled to the second conductive pad. The semiconductor die is attached to the first substrate side and has opposite first and second die sides, and a die terminal along the first die side, the die terminal electrically coupled to the first conductive pad. The molded has a package side, a metal shield along the package side, and a conductive package via that extends through the molded package structure and electrically couples the metal shield to the second conductive pad.

### BACKGROUND

Ball grid array (BGA) and chip-scale package (CSP or WCSP) electronic devices combine small package size with small footprints and high I/O count. As switching speed and power density increase in such packages, electromagnetic interference (EMI) problems increase. One approach to EMI problems is through a grounded lid or sputter shielding metal around the package top and sides, but these approaches are expensive and add multiple process steps and materials cost.

### SUMMARY

In one aspect, an electronic device includes a multilevel package substrate, a semiconductor die, and a molded package structure, where the multilevel package substrate has opposite first and second substrate sides, first and second conductive pads spaced apart from one another along the first substrate side, and a conductive substrate terminal that is exposed along the second substrate side and is electrically coupled to the second conductive pad. The semiconductor die is attached to the first substrate side and has opposite first and second die sides, and a die terminal along the first die side, the die terminal electrically coupled to the first conductive pad. The molded has a package side, a metal shield along the package side, and a conductive package via that extends through the molded package structure and electrically couples the metal shield to the second conductive pad.

In another aspect, a method of fabricating an electronic device includes: attaching a semiconductor die to a first substrate side of a multilevel package substrate with a die terminal of the semiconductor die electrically coupled to a first conductive pad of the multilevel package substrate; forming a molded package structure over the semiconductor die and a portion of the first substrate side; forming a hole through the molded package structure to expose a second conductive pad of the multilevel package substrate or a conductive material above the second conductive pad of the multilevel package substrate; filling the hole with conductive material to form a conductive package via that extends through the molded package structure and contacts the second conductive pad or the conductive material above the second conductive pad; and forming a metal shield along a package side of the molded package structure, the metal shield contacting the conductive package via.

### BRIEF DESCRIPTION OF THE DRAWINGS

FIG. 1 is a top perspective view of an electronic device with a top side shield and through mold vias for shield ground connections.

FIG. 1A is a top plan view of the electronic device of FIG. 1.

FIG. 1B is a partial sectional side elevation view of the electronic device of FIGS. 1 and 1A.

FIG. 2 is a top perspective view of another electronic device with a top side shield and through mold vias for shield ground connections, and second vias above a semiconductor die.

FIG. 2A is a top plan view of the electronic device of FIG. 2.

FIG. 2B is a partial sectional side elevation view of the electronic device of FIGS. 2 and 2A.

FIG. 3 is a top perspective view of another electronic device with a top side shield and through mold vias for shield ground connections, and second vias connecting the package shield to a die shield of a semiconductor die.

FIG. 3A is a top plan view of the electronic device of FIG. 3.

FIG. 3B is a partial sectional side elevation view of the electronic device of FIGS. 3 and 3A.

FIG. 4 is a flow diagram of a method of fabricating an electronic device.

FIG. 5 is a side elevation view of a semiconductor die undergoing a process to form a backside shield thereon.

FIG. 6 is a partial sectional side elevation view of a semiconductor die being flip chip attached to a first substrate side of a multilevel package substrate.

FIG. 7 is a partial sectional side elevation view of another semiconductor die with a backside shield being flip chip attached to a first substrate side of a multilevel package substrate.

FIG. 8 is a partial sectional side elevation view of an electronic device undergoing a ball attach process attaching solder balls to conductive pads on the first substrate side of the multilevel package substrate of FIG. 7.

FIG. 8A is a partial sectional side elevation view of an electronic device undergoing a ball attach process attaching solder balls to conductive pads on the first substrate side of the multilevel package substrate of FIG. 7A.

FIG. 9 is a partial sectional side elevation view of an electronic device undergoing a printing deposition process that deposits conductive metal paste on conductive pads on the first substrate side of the multilevel package substrate of FIG. 7.

FIG. 9A is a partial sectional side elevation view of an electronic device undergoing a printing deposition process that deposits conductive metal paste on conductive pads on the first substrate side of the multilevel package substrate of FIG. 7A.

FIG. 10 is a partial sectional side elevation view of an electronic device undergoing a molding process that forms a molded package structure on the semiconductor die and the multilevel package substrate of FIG. 8.

FIG. 10A is a partial sectional side elevation view of an electronic device undergoing a molding process that forms a molded package structure on the semiconductor die and the multilevel package substrate of FIG. 8A.

FIG. 10B is a partial sectional side elevation view of an electronic device undergoing a molding process that forms a molded package structure on the semiconductor die and the multilevel package substrate of FIG. 9.

FIG. 10C is a partial sectional side elevation view of an electronic device undergoing a molding process that forms a molded package structure on the semiconductor die and the multilevel package substrate of FIG. 9A.

FIG. 11 is a partial sectional side elevation view of an electronic device undergoing a laser ablation process that forms first via holes in the molded package structure of FIG. 10.

FIG. 11A is a partial sectional side elevation view of an electronic device undergoing a laser ablation process that forms first via holes in the molded package structure of FIG. 10A.

FIG. 11B is a partial sectional side elevation view of an electronic device undergoing a laser ablation process that forms first via holes in the molded package structure of FIG. 10B.

FIG. 11C is a partial sectional side elevation view of an electronic device undergoing a laser ablation process that forms first via holes in the molded package structure of FIG. 10C.

FIG. 12 is a partial sectional side elevation view of an electronic device undergoing a laser ablation process that forms second via holes in the molded package structure above the semiconductor die of FIG. 11.

FIG. 12A is a partial sectional side elevation view of an electronic device undergoing a laser ablation process that forms second via holes in the molded package structure above the semiconductor die of FIG. 11A.

FIG. 12B is a partial sectional side elevation view of an electronic device undergoing a laser ablation process that forms second via holes in the molded package structure above the semiconductor die of FIG. 11B.

FIG. 12C is a partial sectional side elevation view of an electronic device undergoing a laser ablation process that forms second via holes in the molded package structure above the semiconductor die of FIG. 11C.

FIG. 13 is a partial sectional side elevation view of the electronic device of FIGS. 1-1B undergoing a deposition process that forms conductive package vias connected to conductive pads on the first substrate side of the multilevel package substrate.

FIG. 13A is a partial sectional side elevation view of an electronic device of FIGS. 2-2B undergoing a deposition process that forms conductive package vias connected to conductive pads on the first substrate side of the multilevel package substrate and second conductive vias above the semiconductor die.

FIG. 13B is a partial sectional side elevation view of an electronic device of FIGS. 3-3B undergoing a deposition process that forms conductive package vias connected to conductive pads on the first substrate side of the multilevel package substrate and second conductive vias connected to the die shield of the semiconductor die.

FIG. 14 is a partial sectional side elevation view of the electronic device of FIGS. 1-1B undergoing a deposition process that forms a metal shield connected to the conductive package vias.

FIG. 14A is a partial sectional side elevation view of an electronic device of FIGS. 2-2B undergoing a deposition process that forms a metal shield connected to the conductive package vias and the second conductive vias above the semiconductor die.

FIG. 14B is a partial sectional side elevation view of an electronic device of FIGS. 3-3B undergoing a deposition process that forms a metal shield connected to the conductive package vias, the second conductive vias, and the die shield of the semiconductor die.

FIG. 15 is a partial sectional side elevation view of the electronic device of FIGS. 1-1B undergoing a ball attach process attaching solder balls to a second substrate side of the multilevel package substrate of FIG. 14.

FIG. 15A is a partial sectional side elevation view of the electronic device of FIGS. 2-2B undergoing a ball attach process attaching solder balls to a second substrate side of the multilevel package substrate of FIG. 14A.

15B is a partial sectional side elevation view of the electronic device of FIGS. 3-3B undergoing a ball attach process attaching solder balls to a second substrate side of the multilevel package substrate of FIG. 14B.

FIG. 16 is a top plan view of another example multilevel package substrate having rectangular substrate pads silkscreened with metallic paste.

FIG. 16A is a top plan view of the multilevel package substrate of FIG. 16 after molding, laser ablation, and deposition of conductive metal in rectangular holes in the molding compound.

### DETAILED DESCRIPTION

In the drawings, like reference numerals refer to like elements throughout, and the various features are not necessarily drawn to scale. Also, the term “couple” or “couples” includes indirect or direct electrical or mechanical connection or combinations thereof. For example, if a first device couples to or is coupled with a second device, that connection may be through a direct electrical connection, or through an indirect electrical connection via one or more intervening devices and connections. One or more operational characteristics of various circuits, systems and/or components are hereinafter described in the context of functions which in some cases result from configuration and/or interconnection of various structures when circuitry is powered and operating. Unless otherwise stated, “about,” “approximately,” or “substantially” preceding a value means +/−10 percent of the stated value.

Described examples include electronic devices and device fabrication methods that provide a shield with through mold vias (TMVs) to connect the shield to a ground or other reference of a multilevel package substrate for cost-effective EMI performance improvement using existing manufacturing equipment. Example implementations can approve EMI radiation by 3× to 4× EMI using a grounded shield, and the described shielding examples are less expensive to produce than grounded lids or sputtered EMI shielding material along the top and sides of the device. In certain examples, via holes can be ablated using standard equipment in a flip chip ball grid array (FCBGA), flip chip CSP (FCCSP), or flip chip wafer-level CSP (FCWCSP) manufacturing line. Multilevel package substrate pad connections for the through mold vias can be enhanced using top side BGAs or screening printing or other deposition of a metallic paste on the top substrate layer using existing equipment. The integrated shield in certain embodiments also improves thermal performance compared with standard lidless solutions, and describes examples provide shielding without the additional cost of forming a package lid. In one example, the metal shield can include ferrous metallic material for enhanced magnetic field reduction in addition to electric field reduction for improved EMI performance.

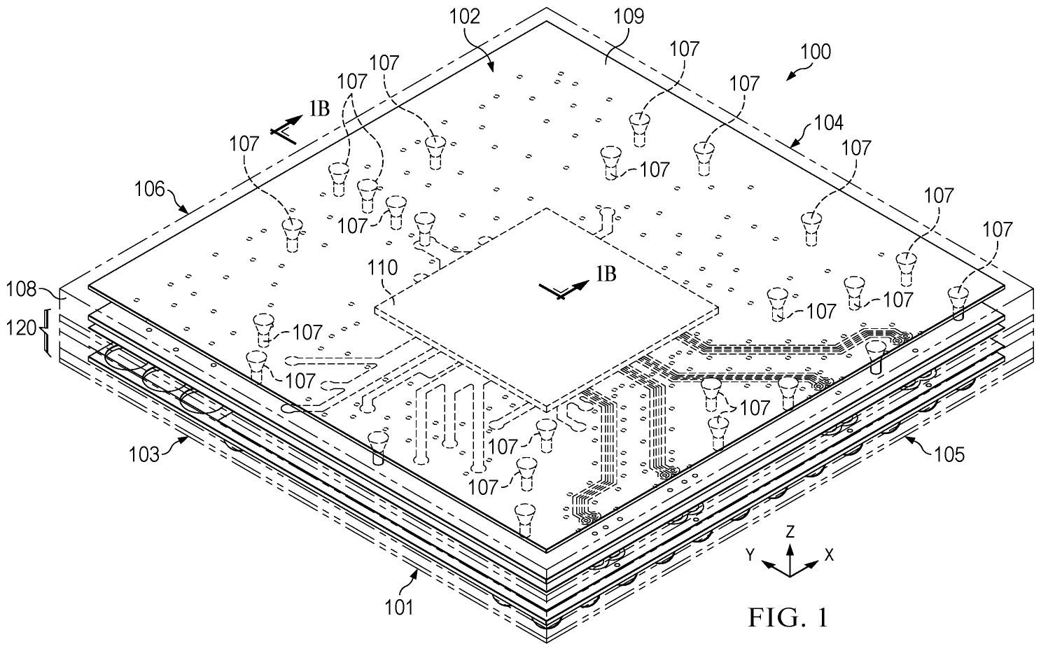

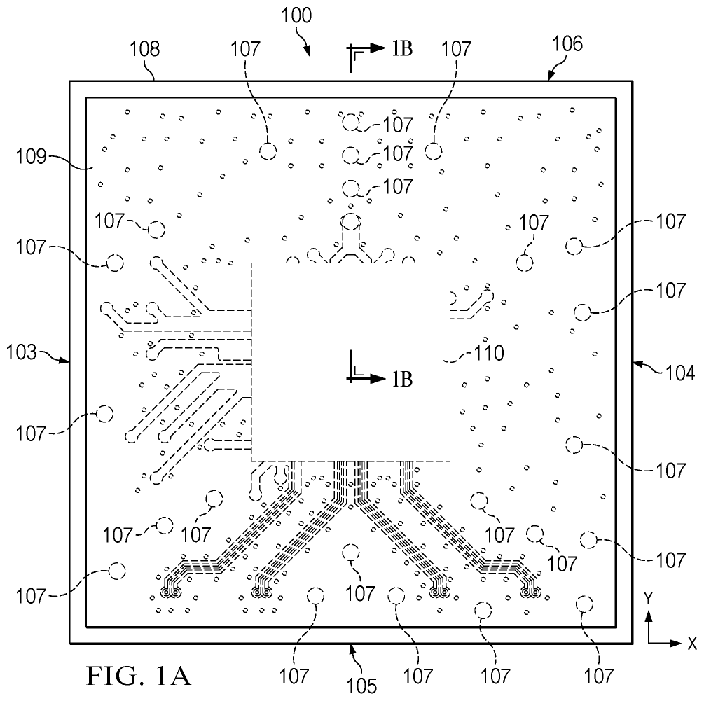

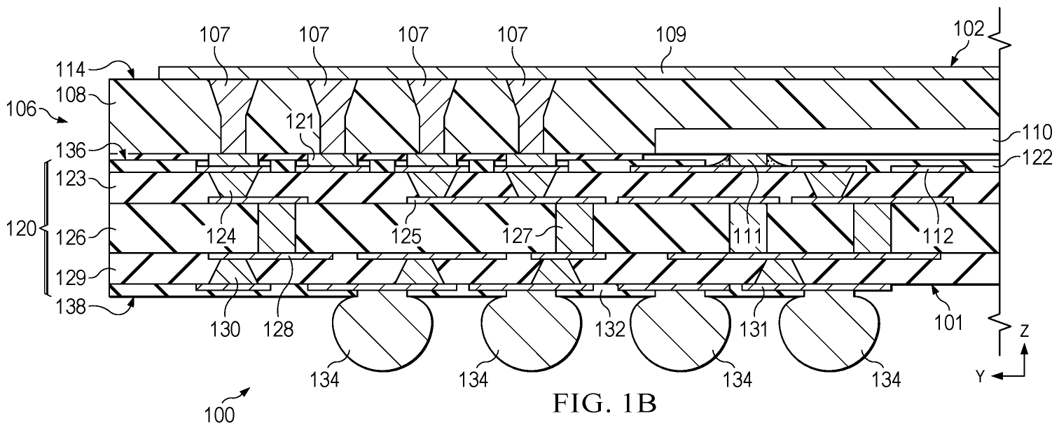

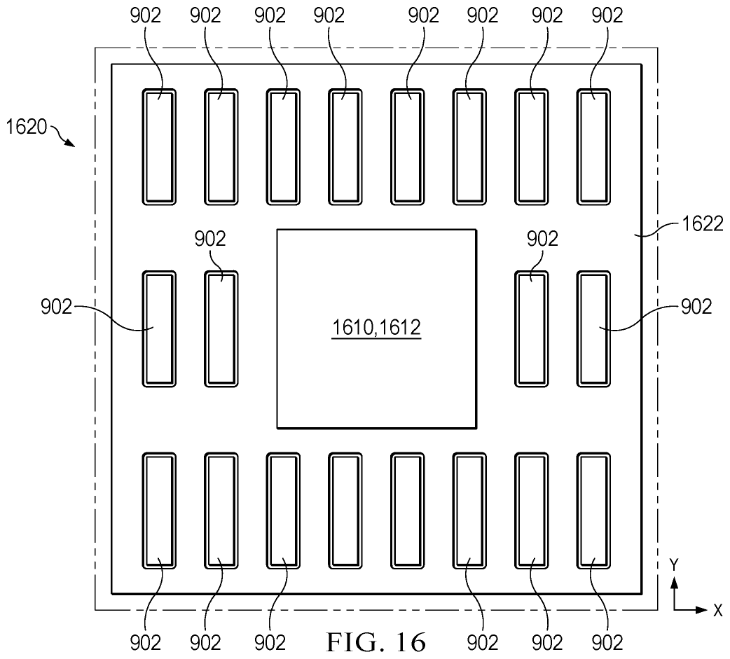

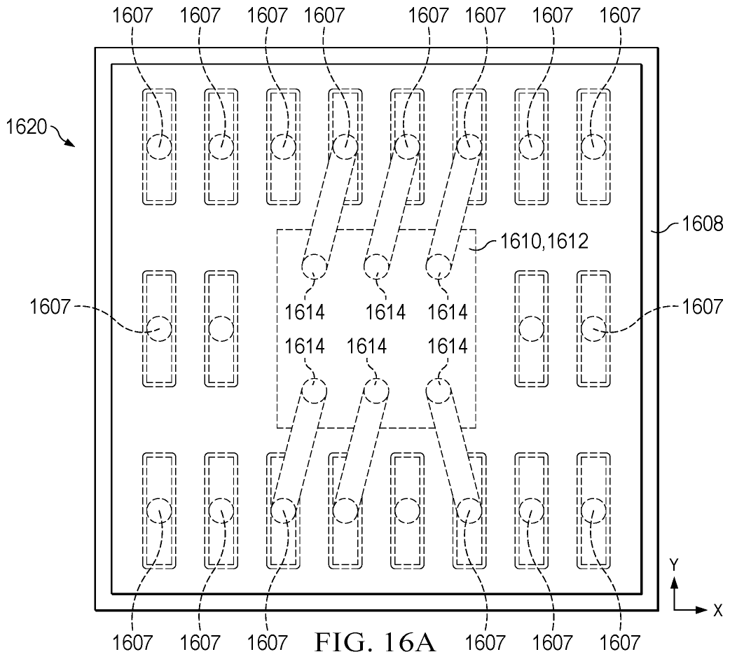

FIGS. 1-B show an example electronic device 100 with a top side shield 109 that extends along a top side 114 of a molded package structure 108, and one or more through mold vias 107 that extend through the molded package structure 108. In one example, the vias 107 are or include copper or other thermally and electrically conductive metal material. In one example, the vias 107 are approximately circular with a diameter of approximately 35 to 48 μm. In other example, the vias 107 can have different shapes or profiles, such as elongated ovals or rectangles (e.g., FIGS. 16 and 16A below). FIG. 1 shows a top perspective view, FIG. 1A shows a top plan view, and FIG. 1B shows a partial sectional side elevation view of the electronic device 100. The molded package structure 108 in one example is or includes plastic or other molding compound. The electronic device 100 has a generally rectangular shape that includes opposite first and second (e.g., bottom and top) sides 101 and 102, respectively, and lateral third, fourth, fifth, and sixth sides 103, 104, 105, and 106, respectively. In one example, the electronic device 100 has a WCSP package structure. In one example, the electronic device has a BGA structure with bottom side solder balls 134 (FIG. 1B) for connection to a host printed circuit board (PCB, not shown). The electronic device 100 is shown in FIGS. 1-1B in an example position or orientation in a three-dimensional space with a first direction X, a perpendicular (orthogonal) second direction Y, and a third direction Z that is perpendicular (orthogonal) to the respective first and second directions X and Y. Structures or features along any two of these respective directions are orthogonal to one another. In the illustrated orientation, the respective first and second sides 101 and 102 are spaced apart from one another along the third direction Z, the respective third and fourth sides 103 and 104 are spaced apart from one another along the first direction X, and the respective fifth and sixth sides 105 and 106 are spaced apart from one another along the second direction Y.

The electronic device 100 includes a semiconductor die 110 flip chip attached to a first substrate side 136 of a multilevel package substrate 120. The semiconductor die 110 has opposite (e.g., bottom and top) first and second die sides, and a die terminal 111 (FIG. 1B) along the first die side. The die terminal 111 is electrically coupled, for example, by conductive solder to a first conductive pad 112 (FIG. 1B) of the multilevel package substrate 120, and includes at least one electronic component (e.g., transistor, diode, capacitor, resistor, inductor, etc.) or multiple components arranged in one or more circuits (not shown). In other examples, the electronic device 100 includes one or more additional electronic components soldered to top side conductive pads of the multilevel package substrate 120, such as a second die, passive components, transformers, etc. (not shown).

As best shown in FIG. 1B, the multilevel package substrate 120 has opposite (e.g., top and bottom) first and second substrate sides 136 and 138, and respective first and second conductive pads 112 and 121 are spaced apart from one another along the first substrate side 136. The multilevel package substrate 120 can include any number of levels, with conductive features (e.g., metals that are or include aluminum, copper, SAC305, etc. or other conductive metal or combinations thereof) and laminated dielectric or insulator layers, such as organic materials. The patterned conductive traces and vias of the multilevel package substrate 120 provide signal and power routing and electrical interconnections that form one or more electrical circuits and may include one or more components of the semiconductor die 110.

The illustrated multilevel package substrate 120 includes a patterned solder mask layer 122 of a first or top level. The solder mask layer 122 has openings around certain structures, including openings around the respective first and second conductive pads 112 and 121. The top or first level includes a laminate dielectric or insulator layer 123, and the conductive pads 112 and 121 and the solder mask layer 122 are formed on a top side if the insulator layer 123.

A second (e.g., middle) level of the multilevel package substrate 120 includes a core dielectric or insulator layer 126 with a patterned conductive trace layer 125 on a top side of the insulator layer 126, and the first level includes conductive metal vias 124 that extend between conductive traces of the trace layer 125 and the conductive features (e.g., conductive substrate pads 112 and 121) of the first level. Conductive metal vias 127 extend through the core layer 126 to interconnect select portions of the patterned conductive trace layer 125 to patterned conductive metal features of a trace layer 128 on the bottom side of the core layer 126.

A third level in this example includes another dielectric or insulator layer 129 extending over the patterned conductive trace layer 125 and the bottom side of the core layer 126. Conductive metal vias 130 extend through the dielectric or insulator layer 129 to interconnect select portions of the patterned conductive metal features of the trace layer 128 and bottom side metal pads or conductive substrate terminals 131 formed on select portions of the bottom side of the vias 130 and the dielectric or insulator layer 129. The bottom or second side 138 of the multilevel package substrate 120 has a patterned solder mask layer 132 with openings for certain ones of the conductive substrate terminals 131, for example, to facilitate attachment of the solder balls 134 to respective ones of the terminals 131. The conductive substrate terminal 131 and the associated bottom side solder ball 134 are exposed along the second substrate side 138 and electrically coupled to the second conductive pad 121 by a set of the conductive routing traces and vias of the multilevel package substrate 120.

The molded package structure 108 encloses the semiconductor die 110 and a portion of the first substrate side 136. The metal shield 109 extends along all or a portion of the top package side 114. In one example, the metal shield is or includes copper or other electrically and thermally conductive metal. In one example, the metal shield 109 has a thickness of approximately 15 μm along the third direction Z. The conductive package vias 107 extend through the molded package structure 108 along the third direction Z and electrically couple the metal shield 109 to the second conductive pad 121. In one example, the second conductive pad 121 is electrically coupled through patterned conductive traces and vias of the multilevel package substrate 120 to one or more of the bottom side terminals 131 and associated solder balls 134. This allows electrical connection of the metal shield 109 to a circuit ground or other electrical reference node of a host PCB (not shown). The shield 109, the through mold vias 107 and the connections through the multilevel package substrate 120 provide an electrical shield that reduces electric field emissions from the electronic device 100. In addition, the shield 109, the through mold vias 107 and the connections through the multilevel package substrate 120 enhance thermal performance by facilitating heat removal from the semiconductor die 110 and any other included electronic components and provide a thermal path to a host PCB. In one implementation, an external heat sink can be attached to the exposed top side of the metal shield 109 to further help heat transfer. In one example, the metal shield (109) is or includes copper. In a further example, the metal shield (109) is or includes a ferrite or ferrous metal material to help reduce magnetic field emissions from the electronic device 100.

The multilevel package substrate 120 in the illustrated example includes multiple instances of the second conductive pad 121 and each instance of the second conductive pad 121 is electrically coupled to the conductive substrate terminal 131, 134 through patterned conductive traces and vias of the multilevel package substrate 120. The molded package structure 108 has multiple instances of the conductive package via 107, and each instance of the conductive package via 107 extends through the molded package structure 108 and electrically couples the metal shield 109 to the second conductive pad 121. The provision of multiple through mold vias 107 and associated connections to the shield 109 further enhances the shield performance with respect to EMI reduction as well as enhancing the thermal heat removal advantages.

In the example of FIGS. 1-1B, the semiconductor die 110 is located in an interior region of the electronic device 100 and the semiconductor die 110 is spaced apart from the four lateral sides 103-106. In this example, a first instance of the conductive package via 107 is spaced apart from and between the semiconductor die 110 and the first lateral side 103, a second instance of the conductive package via 107 is spaced apart from and between the semiconductor die 110 and the second lateral side 104, a third instance of the conductive package via 107 is spaced apart from and between the semiconductor die 110 and the third lateral side 105, and a fourth instance of the conductive package via 107 is spaced apart from and between the semiconductor die 110 and the fourth lateral side 106. This creates a lateral shield structure encirclement of the semiconductor die 110 to help reduce and contain EMI emissions and provide lateral heat removal along all four lateral sides 103-106 of the electronic device 100. In other implementations, the lateral shield components are elongated, and further lateral shield structures are provided to encircle the interior portion more completely with the semiconductor die 110, for example, as illustrated and described further below in connection with FIGS. 16 and 16A.

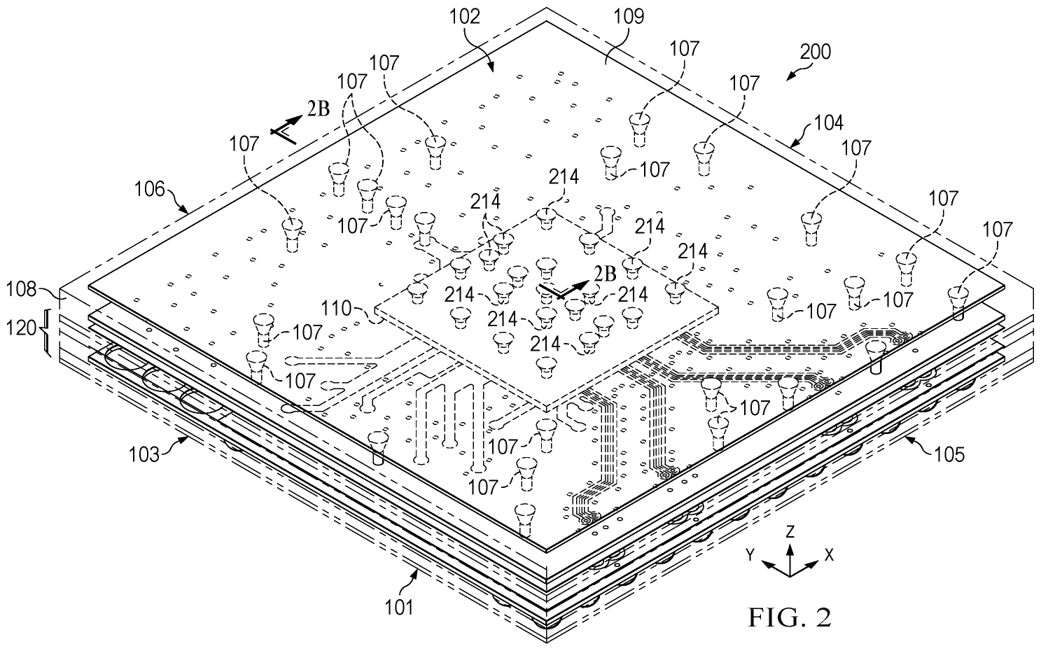

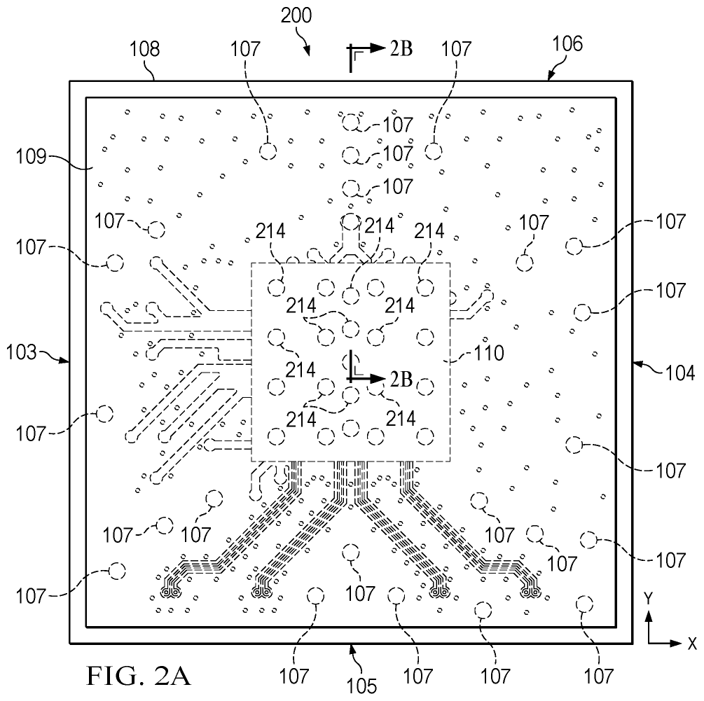

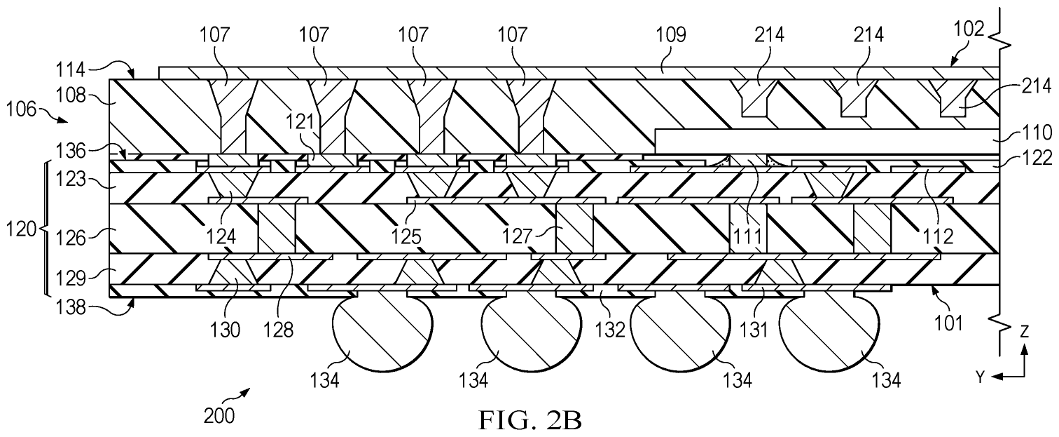

FIGS. 2-2B show respective perspective, top, and sectional side views of another electronic device 200 with a top side shield 109 and one or more through mold vias 107 for shield ground connections and other similarly numbered structures and features as described above in connection with FIGS. 1-1B. In addition, the molded package structure 108 in the electronic device 200 of FIGS. 2-2B has one or more second conductive vias 214 that contact the metal shield 109 and extend into the molded package structure 108 toward the second die side of the semiconductor die 110. In one example, the second conductive vias 214 are spaced apart from the second die side. The molded package structure 108 in FIGS. 2-2B has multiple instances of the second conductive via 214, and each instance of the second conductive via 214 contacts the metal shield 109 and extends into the molded package structure 108 toward the second die side, and each instance of the second conductive via 214 is spaced apart from the second die side. The second conductive vias 214 enhance thermal performance by providing a thermally conductive structure to help extract heat from the back side of the semiconductor die 110.

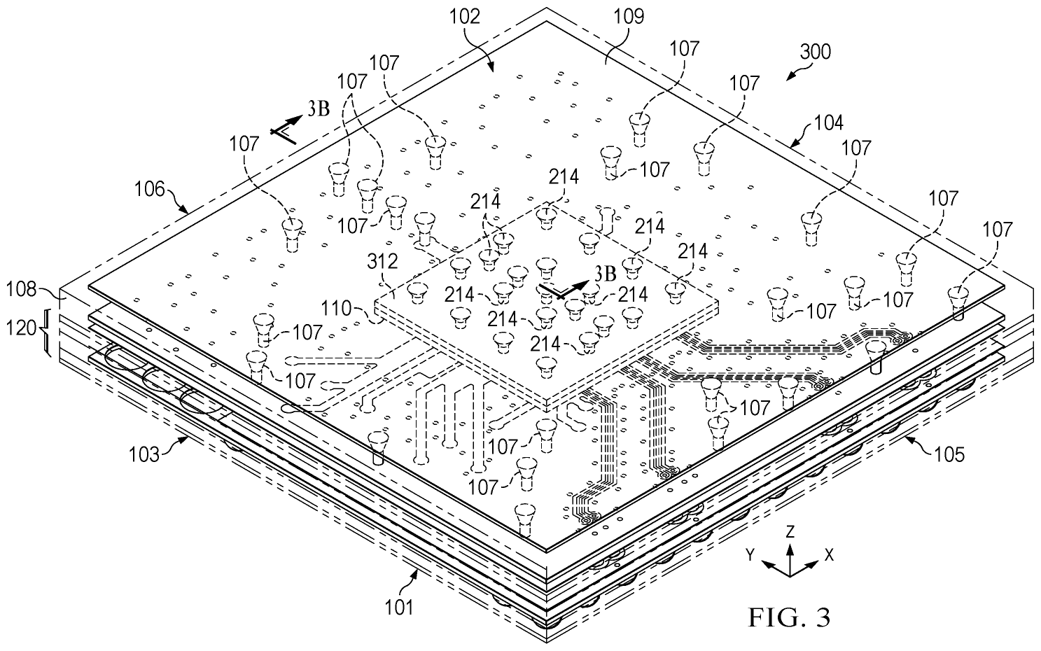

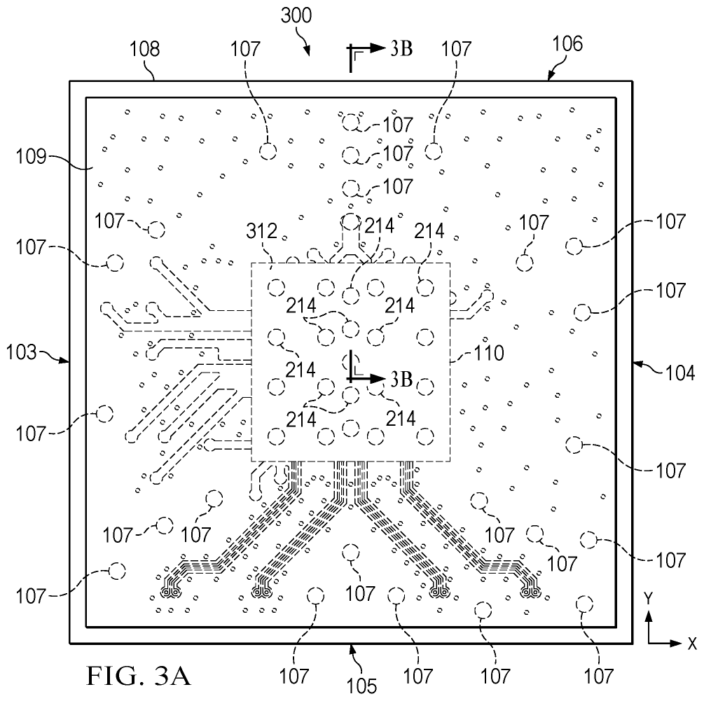

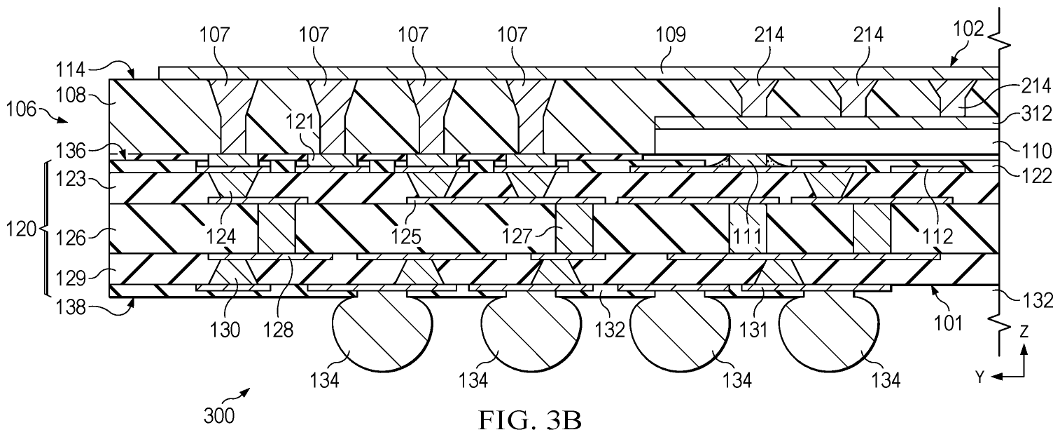

FIGS. 3-3B show respective perspective, top, and sectional side views of yet another example electronic device 300 with a top side shield 109, through mold vias 107 for shield ground connections and other similarly numbered structures and features as described above in connection with FIGS. 1-2B. In this example, the semiconductor die 110 has a second metal shield 312 (e.g., a copper or aluminum die shield) along the second die side, and the second conductive via 214 extends through the molded package structure 108 and electrically couples the top metal shield 109 to the second metal shield 312. In the illustrated example, the molded package structure 108 has multiple instances of the second conductive via 214 and each instance of the second conductive via 214 extends through the molded package structure 108 and electrically couples the metal shield 109 to the second metal shield 312.

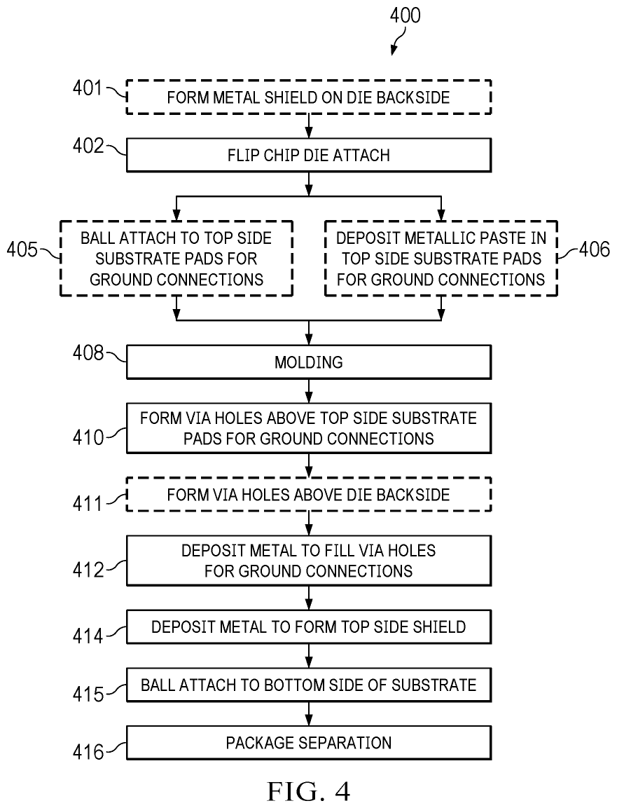

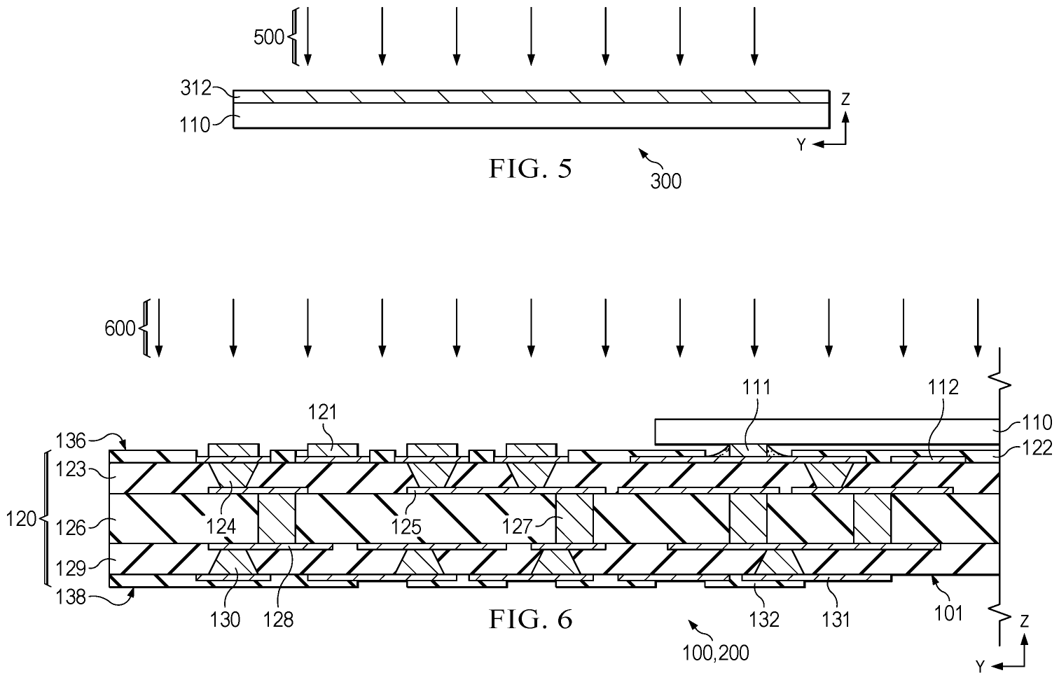

Referring now to FIGS. 4-15B, FIG. 4 shows a method 400 of fabricating an electronic device and FIGS. 5-15B show various implementations of the method 400 during fabrication of the example electronic device 100, 200, and 300. In one implementation, the method 400 includes forming a conductive metal shield on a semiconductor die at 401 in FIG. 4. FIG. 5 shows one example that includes performing a deposition process 500 that deposits copper or other suitable conductive metal on the second die side of the semiconductor die 110 to form the second metal shield 312 described above in connection with the electronic device 300 of FIGS. 3-3B. In one implementation, the deposition process 500 is performed during wafer processing prior to die singulation. In other implementations, the die shield formation at 401 is omitted (e.g., to fabricate the electronic devices 100 or 200 above).

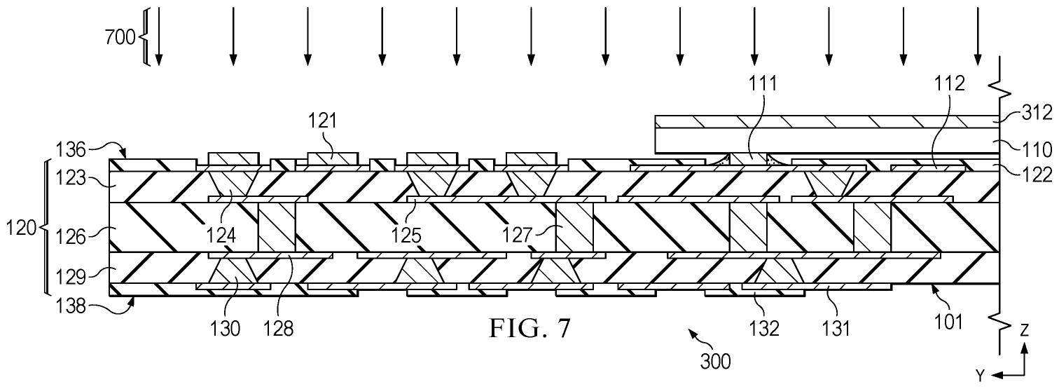

The processing at 402-414 in FIG. 4 is performed in one example in a panel array with multiple rows and columns of unit areas concurrently processed before individual finished electronic devices are separated at 416 from the panel array structure. The method 400 in FIG. 4 includes attaching a semiconductor die to a first substrate side of a multilevel package substrate at 402. FIG. 6 shows one example during fabrication of the electronic devices 100 and 200 of FIGS. 1-2B above. This example includes performing a flip chip die attach process 600 that attaches the semiconductor die 110 to the first substrate side 136 of the multilevel package substrate 120 with the die terminal 111 of the semiconductor die 110 electrically coupled to the first conductive pad 112 of the multilevel package substrate 120, for example, by a solder connection.

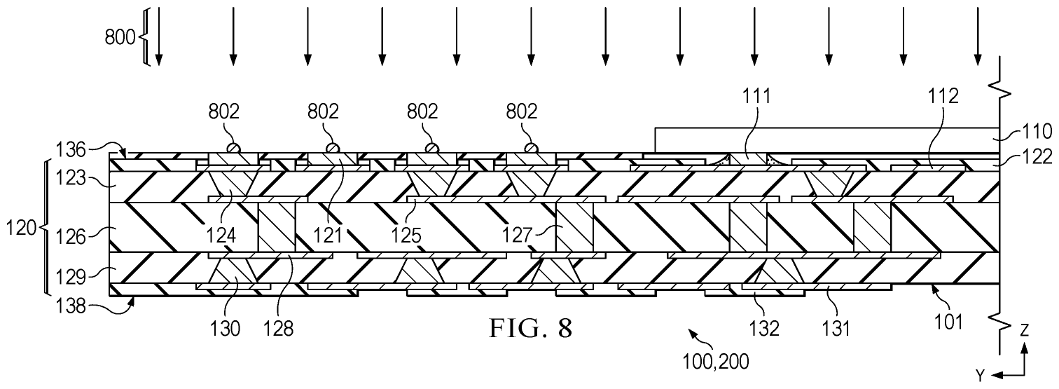

FIG. 7 shows another example of the die attach processing at 402 in FIG. 4 during fabrication of the electronic device 300 of FIGS. 3-3B above. This example includes performing a flip chip die attach process 700 that attaches the back side shielded semiconductor die 110 to the first substrate side 136 of the multilevel package substrate 120 with the die terminal 111 of the semiconductor die 110 electrically coupled to the first conductive pad 112 of the multilevel package substrate 120, for example, by a solder connection.

The method 400 in one example includes forming solder balls or metallic paste or other conductive metal material on conductive pads on the first substrate side of the multilevel package substrate at 405 or 406 in FIG. 4 before forming the molded package structure 108 at 408. In other implementations, the addition of solder balls or metallic paste or other conductive metal material at 405 or 406 is omitted, and the method 400 proceeds to molding at 408. The solder balls attached at 405 or the metallic material deposited at 406 provide metallic interconnection between conductive pads of the multilevel package substrate and subsequently formed conductive metal of through mold vias. In implementations where the processing at 405 and 406 is omitted, subsequently formed metal via material makes direct mechanical and electrical contact with the conductive pads on the first substrate side of the multilevel package substrate.

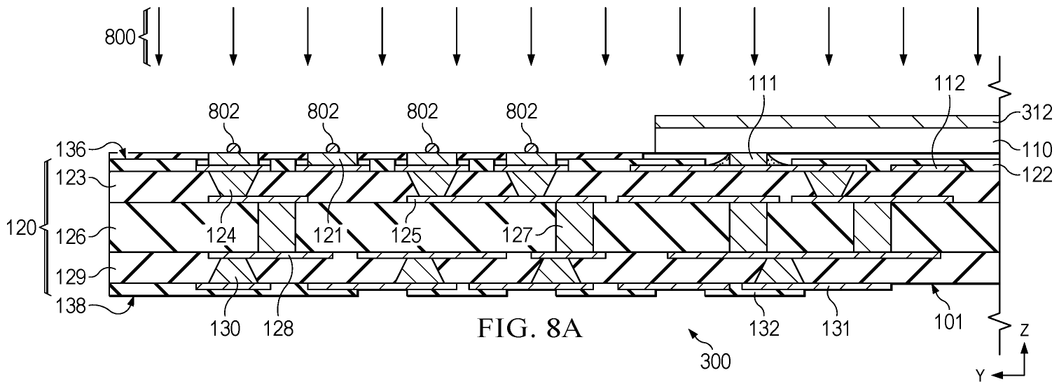

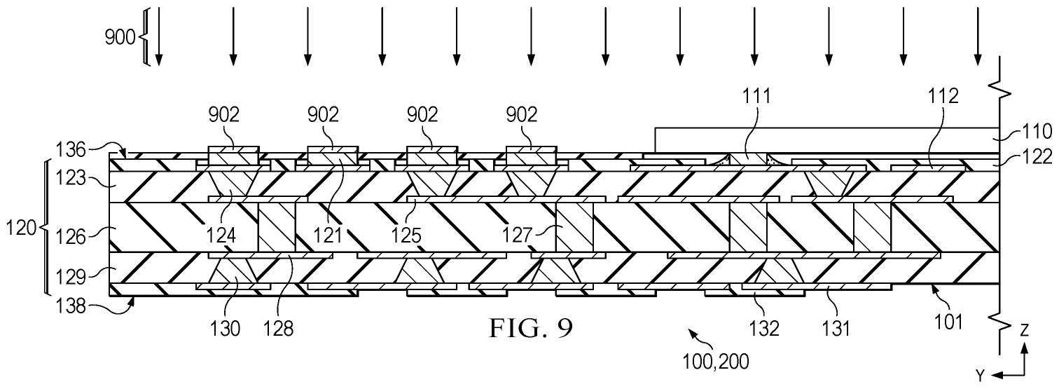

At 405 in one example, the method includes attaching solder balls to the second conductive pads 121. FIGS. 8 and 8A show two examples of solder ball attachment processing at 405 in FIG. 4. The example of FIG. 8 shows one example during fabrication of the electronic devices 100 and 200 of FIGS. 1-2B above, including performing an attachment process 800 that attaches solder balls 802 to the second conductive pads 121 on the first substrate side 136 of the multilevel package substrate 120. FIG. 8A a shows another example of the ball attach processing at 405 in FIG. 4 during fabrication of the electronic device 300 of FIGS. 3-3B above with the back side shielded semiconductor die 110. This example includes performing the ball attach process 800 that attaches solder balls 802 to the second conductive pads 121 on the first substrate side 136 of the multilevel package substrate 120.

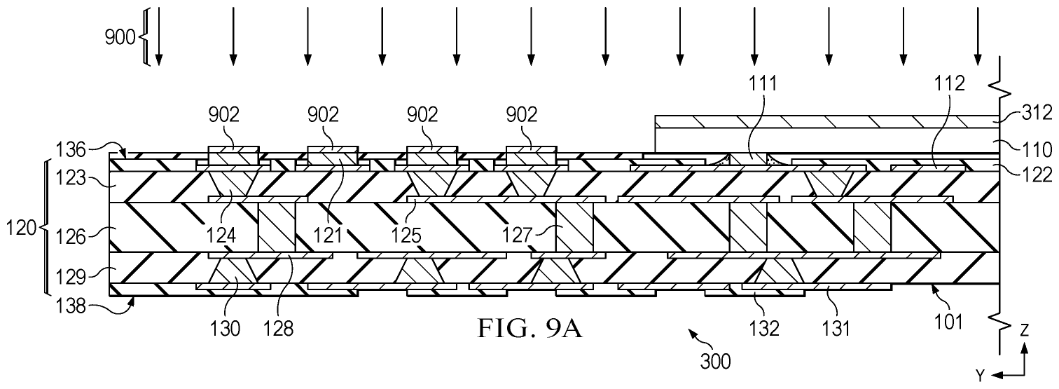

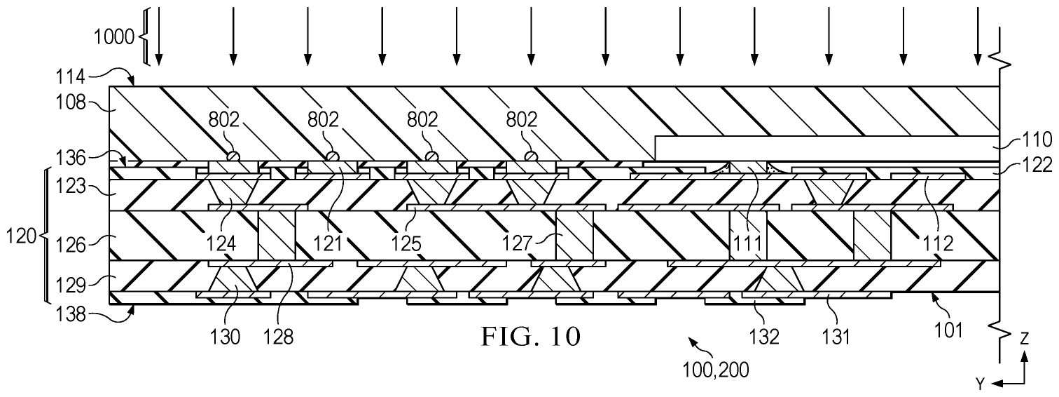

In alternate implementations at 406 in FIG. 4, the method includes depositing a conductive paste on the second conductive pads 121 of the multilevel package substrate 120 before forming the molded package structure 108. FIGS. 9 and 9A show two examples of conductive paste deposition processing at 406 in FIG. 4. The example of FIG. 9 shows one example during fabrication of the electronic devices 100 and 200 of FIGS. 1-2B above, including performing a deposition process 900 that deposits conductive metal paste 902 on the second conductive pads 121 on the first substrate side 136 of the multilevel package substrate 120. FIG. 9A a shows another example of the conductive paste deposition processing at 406 in FIG. 4 during fabrication of the electronic device 300 of FIGS. 3-3B above with the back side shielded semiconductor die 110. This example includes performing the deposition process 900 that deposits conductive metal paste 902 on the second conductive pads 121 on the first substrate side 136 of the multilevel package substrate 120.

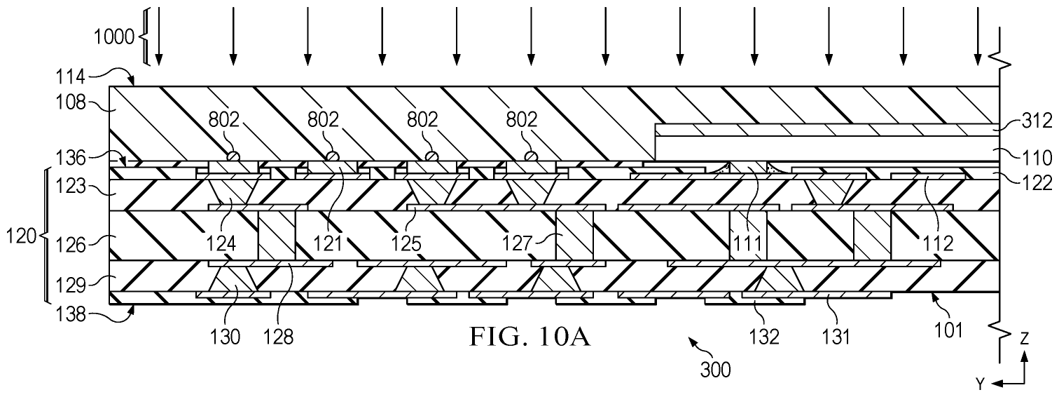

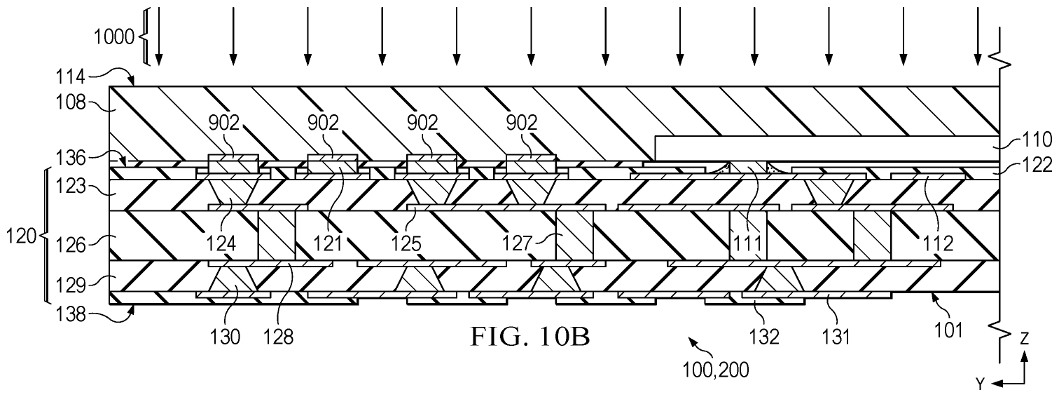

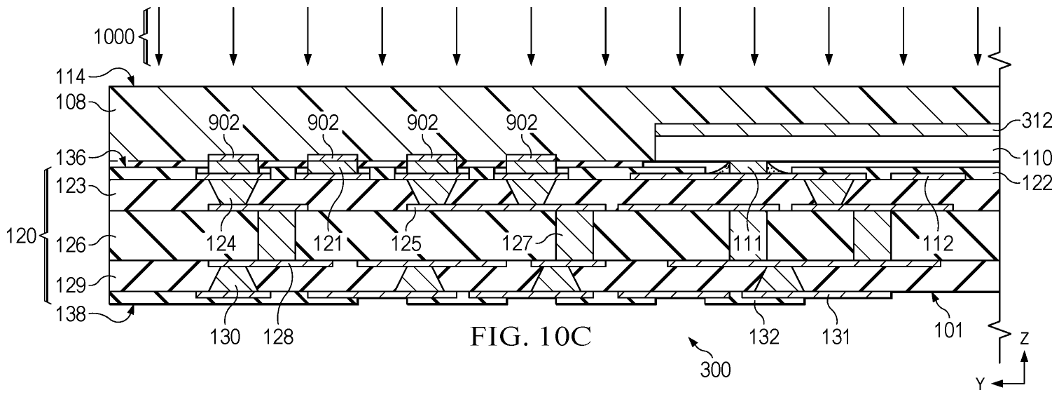

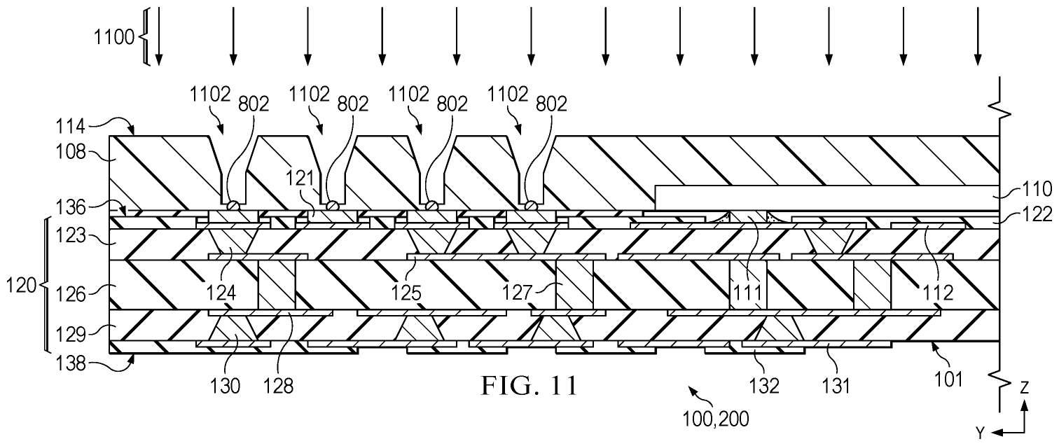

The method 400 in FIG. 4 continues at 408 with forming a molded package structure over the semiconductor die and a portion of the first substrate side 136. FIGS. 10 and 10A show example implementations of the molding processing at 408 during fabrication of the electronic devices 100, 200 and 300 above having solder balls 802 on the second conductive substrate pads 121. FIG. 10 shows one example during fabrication of the electronic devices 100 and 200 that includes performing a molding process 1000 that forms the molded package structure 108 over the semiconductor die 110 and a portion of the first substrate side 136 of the multilevel package substrate 120 of FIG. 8. FIG. 10A shows another example during fabrication of the electronic device 300 that includes performing the molding process 1000 that forms the molded package structure 108 over the semiconductor die 110 and a portion of the first substrate side 136 of the multilevel package substrate 120 of FIG. 8A.

FIGS. 10B and 10C show further example implementations of the molding processing at 408 during fabrication of the electronic devices 100, 200 and 300 having conductive solder 902 on the second conductive substrate pads 121. FIG. 10B shows one example that includes performing the molding process 1000 that forms the molded package structure 108 over the semiconductor die 110 and a portion of the first substrate side 136 of the multilevel package substrate 120 of FIG. 9. FIG. 10C shows another example that includes performing the molding process 1000 that forms the molded package structure 108 over the semiconductor die 110 and a portion of the first substrate side 136 of the multilevel package substrate 120 of FIG. 9A.

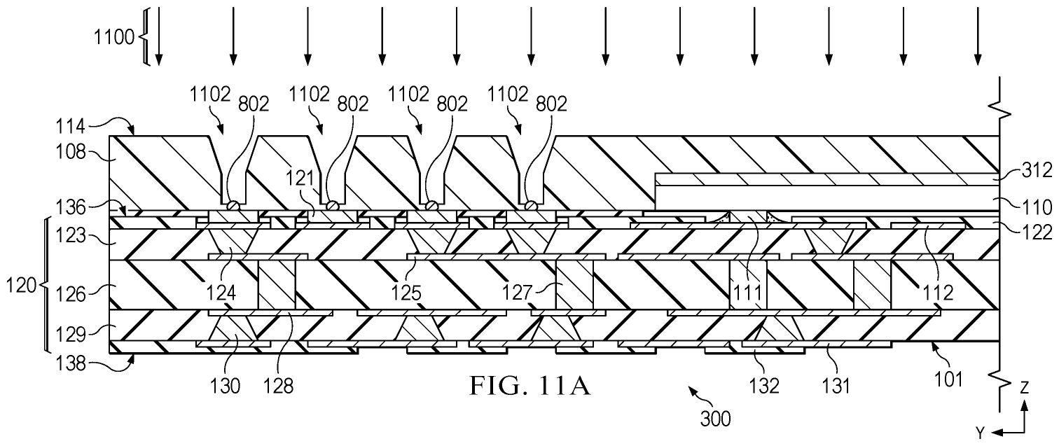

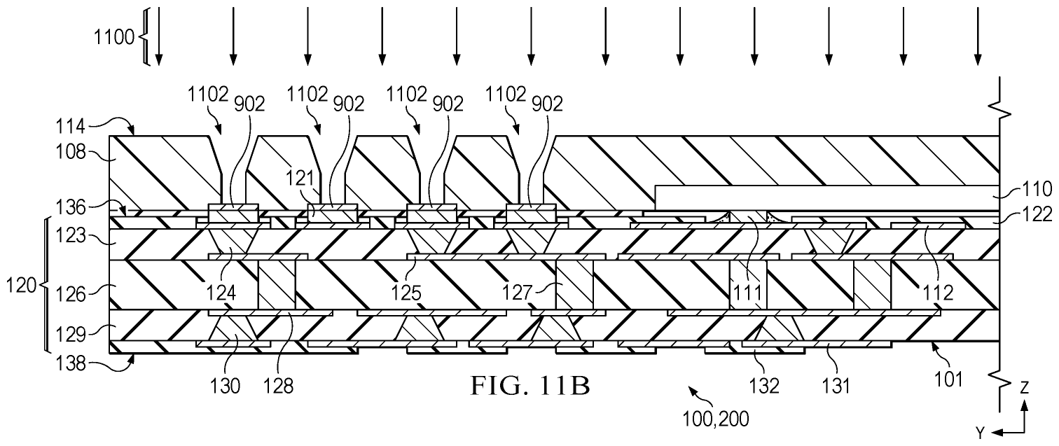

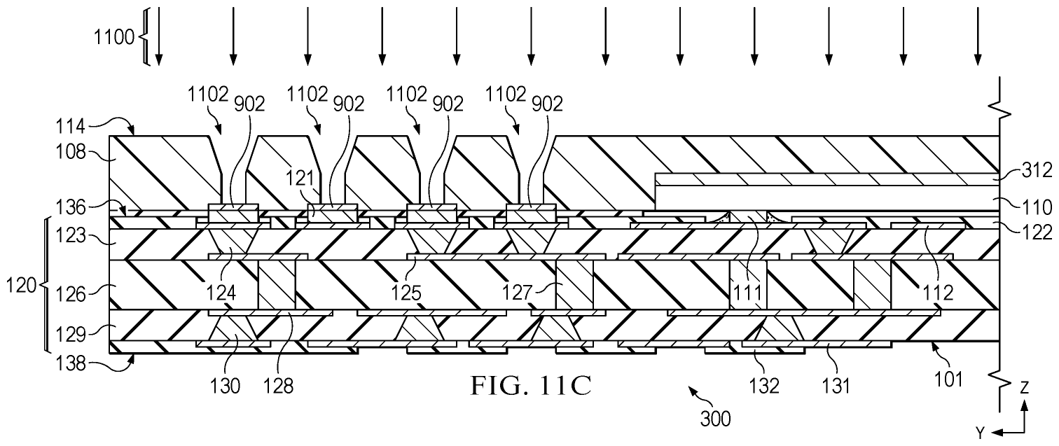

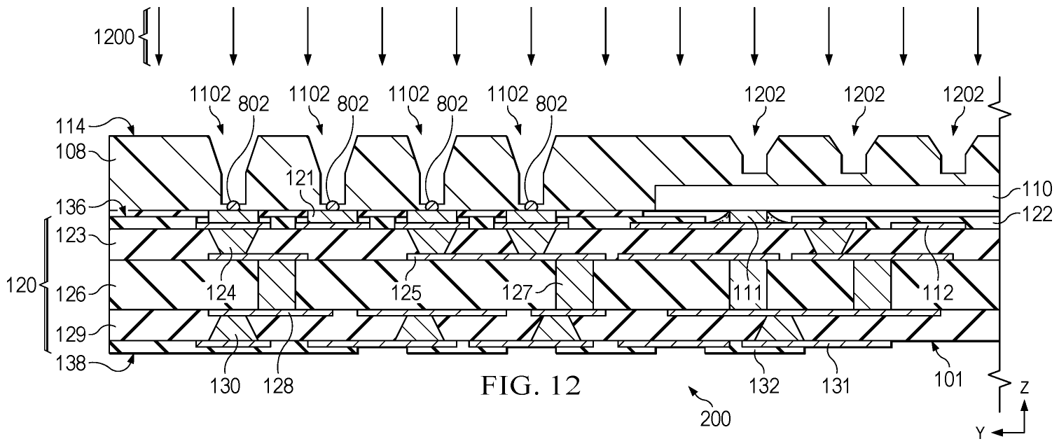

The method 400 continues at 410 in FIG. 4 with forming first via holes through the molded package structure 108 to expose the respective second conductive pads 121 or a conductive material (e.g., solder balls 802, conductive paste 902, etc.). FIGS. 11 and 11A show example implementations of the via hole formation processing at 410 during fabrication of the electronic devices 100, 200 and 300 above having the solder balls 802 on the second conductive substrate pads 121. FIGS. 11B and 11C show example implementations of the via hole formation processing at 410 during fabrication of the electronic devices 100, 200 and 300 above having the conductive metal paste 902 on the second conductive substrate pads 121. In another example, the via hole formation at 410 exposes the respective second conductive pads 121 along the first substrate side 136 of the multilevel package substrate 120. Any suitable material removal process techniques and steps can be used to form the via holes at 410, including one or more of laser ablation, chemical etching, or combinations thereof.

FIG. 11 shows one example during fabrication of the electronic devices 100 and 200 that includes performing a laser ablation process 1100 that forms holes 1102 through the molded package structure 108 to expose the conductive material (e.g., the solder balls) 802 above the respective second conductive pads 121 of the multilevel package substrate 120 of FIG. 10. FIG. 11A shows another example during fabrication of the electronic device 300 that includes performing the laser ablation process 1100 that forms holes 1102 through the molded package structure 108 to expose the conductive material (e.g., the solder balls) 802 above the respective second conductive pads 121 of the multilevel package substrate 120 of FIG. 10A. FIG. 11B shows another example during fabrication of the electronic devices 100 and 200 that includes performing the laser ablation process 1100 that forms holes 1102 through the molded package structure 108 to expose the conductive material (e.g., the deposited conductive paste) 902 above the respective second conductive pads 121 of the multilevel package substrate 120 of FIG. 10B. FIG. 11C shows another example during fabrication of the electronic device 300 that includes performing the laser ablation process 1100 that forms holes 1102 through the molded package structure 108 to expose the conductive material (e.g., the deposited conductive paste) 902 above the respective second conductive pads 121 of the multilevel package substrate 120 of FIG. 10C.

In some examples (e.g., in the formation of the electronic devices 200 and 300 above), the method 400 includes processing at 411 to form second via holes above the semiconductor die 110. In one example, the second via holes can be formed by the process 1100 used to form the first via holes 1102. In other implementations, a separate material removal process (e.g., laser ablation, etching, etc.) can be used to form the second via holes at 411 in FIG. 4.

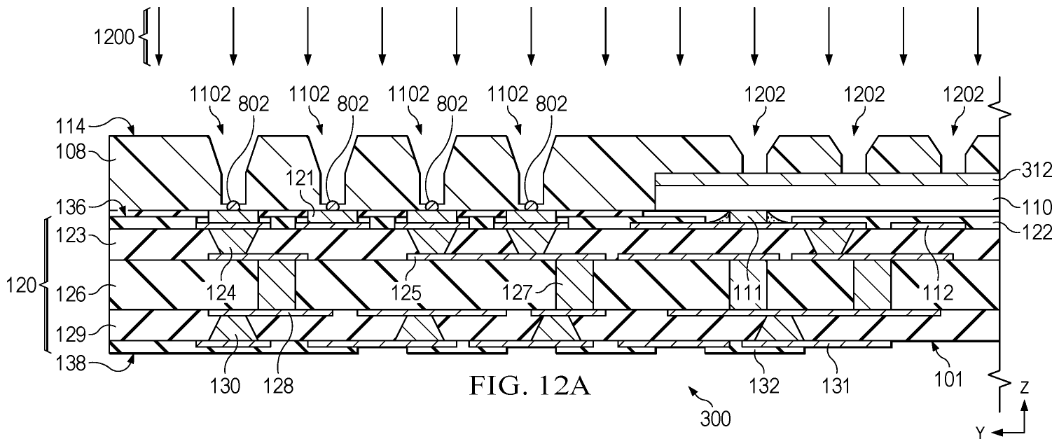

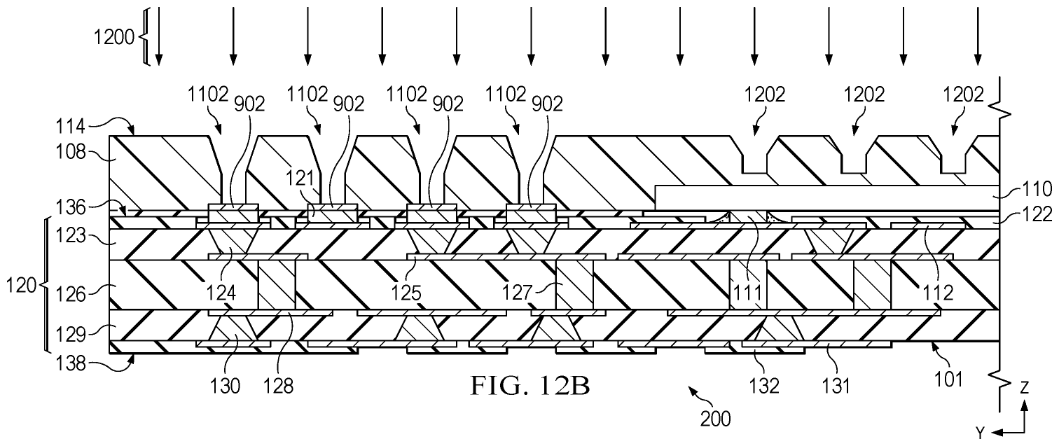

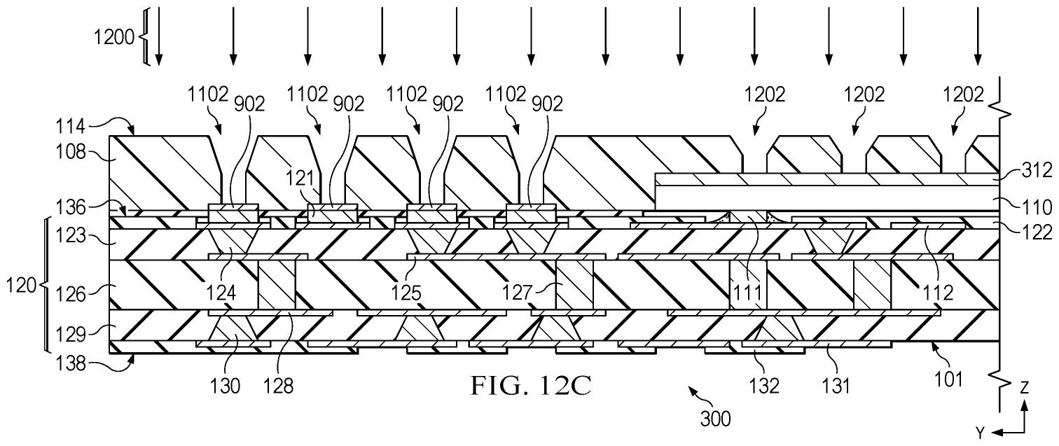

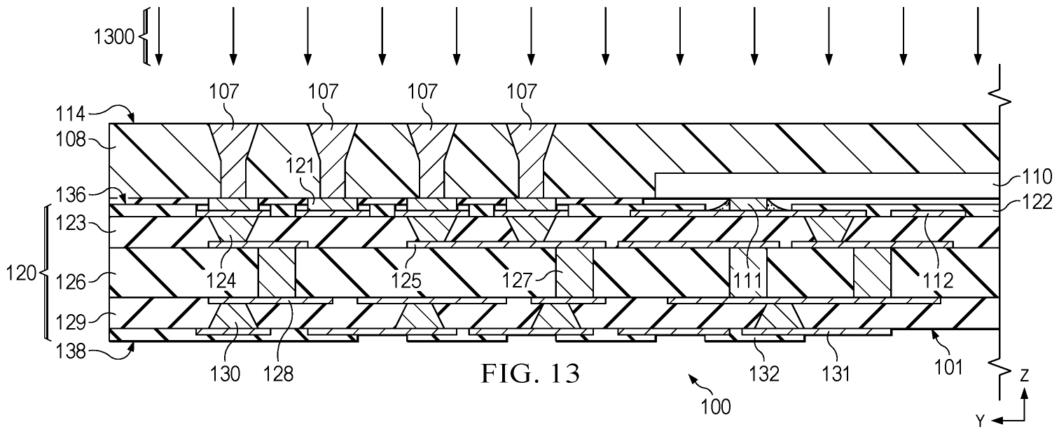

FIGS. 12 and 12A show example implementations of the second via hole formation processing at 411 during fabrication of the electronic devices 200 and 300 above having the solder balls 802 on the second conductive substrate pads 121. FIGS. 12B and 12C show example implementations of the second via hole formation processing at 411 during fabrication of the electronic devices 200 and 300 above having the conductive metal paste 902 on the second conductive substrate pads 121. FIG. 12 shows one example during fabrication of the electronic device 200 that includes performing a second laser ablation process 1200 (or a continuation of the first laser ablation process 1100 of FIG. 11A above) that forms the second via holes 1202 through the molded package structure 108 above the non-shielded semiconductor die 110. In this example, the bottoms of the second via holes 1202 are spaced apart from the second die side of the semiconductor die 110. FIG. 12A shows another example during fabrication of the electronic device 300 that includes performing the laser ablation process 1200 (or a continuation of the first laser ablation process 1100) that forms the second via holes 1202 that extend through the molded package structure 108 and expose respective portions of the top side of the die shield 312.

FIG. 12B shows another example during fabrication of the electronic device 200 that includes performing the second laser ablation process 1200 (or a continuation of the first laser ablation process 1100) that forms the second via holes 1202 through the molded package structure 108 above the non-shielded semiconductor die 110, with the second via holes 1202 spaced apart from the second die side of the semiconductor die 110. FIG. 12C shows another example during fabrication of the electronic device 300 that includes performing the laser ablation process 1200 (or a continuation of the first laser ablation process 1100) that forms the second via holes 1202 that extend through the molded package structure 108 and expose respective portions of the top side of the die shield 312.

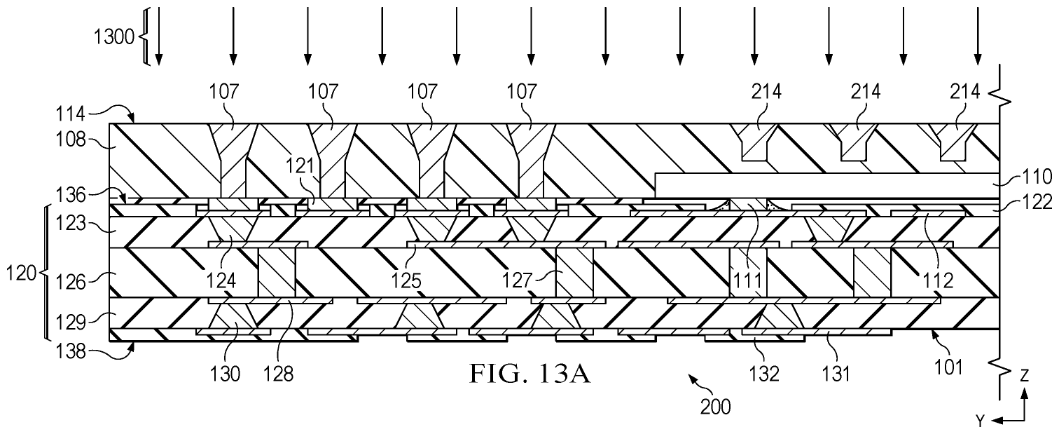

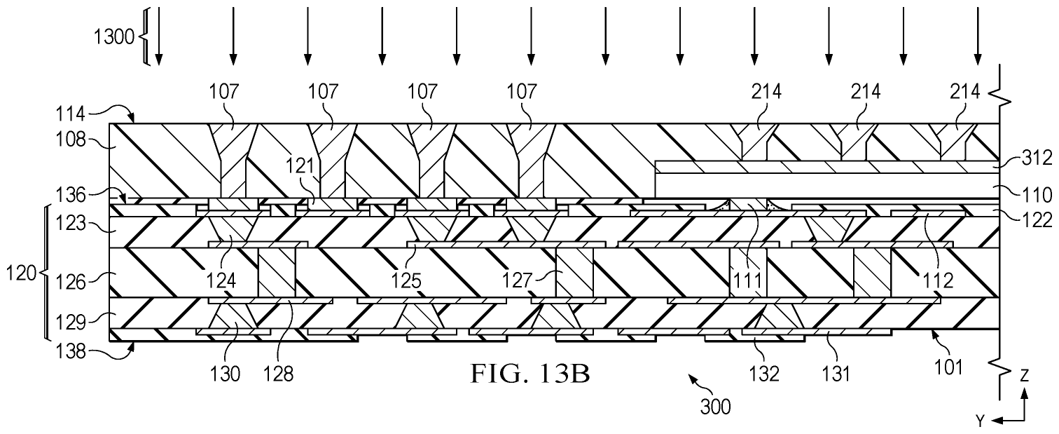

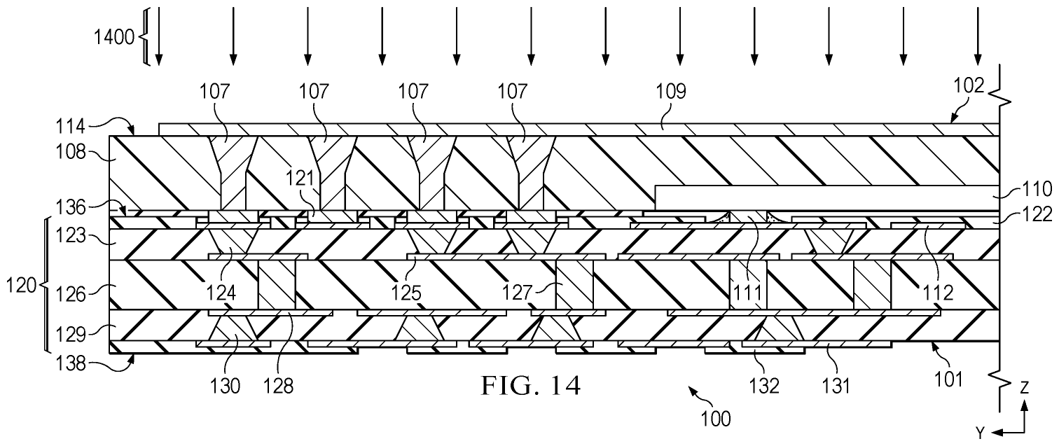

The method 400 continues at 412 in FIG. 4 with filling the via holes 1102 with conductive metal (e.g., that is or includes copper, aluminum, or other conductive metal) to form the conductive vias 107 that extend through the molded package structure 108 and contact a respective one of the second conductive pads 121 or the conductive material 802, 902 above the second conductive pad 121 of the multilevel package substrate 120. In certain implementations (e.g., during fabrication of the electronic devices 200 and 300), the via hole filling at 412 also fills the second via holes 1202 to form the second conductive vias 214. FIG. 13 shows one example of the via hole filling at 412 during fabrication of the electronic device 100 of FIGS. 1-1B above. This example includes performing a deposition process 1300 that fills the first via holes 1102 with conductive material to form the conductive package vias 107 that extend through the molded package structure 108 and contact a respective one of the solder balls 802, conductive paste 902, or directly contact the respective second conductive pad 121 of the multilevel package substrate 120.

FIG. 13A shows another example during fabrication of the electronic device 200 that includes performing the deposition process 1300 that fills the first via holes 1102 with conductive material to form the conductive package vias 107 that extend through the molded package structure 108 and contacts a respective one of the solder balls 802, conductive paste 902 or directly contacts the second conductive pads 121 of the multilevel package substrate 120. The deposition process 1300 in this example also fills the second via holes 1202 to form the second conductive vias 214 that extend toward but are spaced apart from the second die side of the semiconductor die 110.

FIG. 13B shows another example during fabrication of the electronic device 300 of FIGS. 3-3B. This example includes performing the deposition process 1300 that fills the first via holes 1102 with conductive material to form the conductive package vias 107 that extend through the molded package structure 108 and contacts a respective one of the solder balls 802, conductive paste 902 or directly contacts the second conductive pads 121 of the multilevel package substrate 120. The deposition process 1300 in this example also fills the second via holes 1202 to form the second conductive vias 214 that extend to the die shield 312 of the semiconductor die 110.

The method 400 continues at 414 in FIG. 4 with forming the metal shield 109. In one example, the processing at 414 continues a deposition process used at 412. In another implementation, a separate deposition process is used at 414 to form the metal shield 109. In one implementation, the shield formation at 414 includes depositing a metal material that is or includes copper, aluminum, or other conductive metal. In these or another example, the shield formation at 414 includes depositing a metal material that is or includes a ferrous metal, for example, to enhance EMI performance with respect to magnetic field (e.g., H-field) radiation).

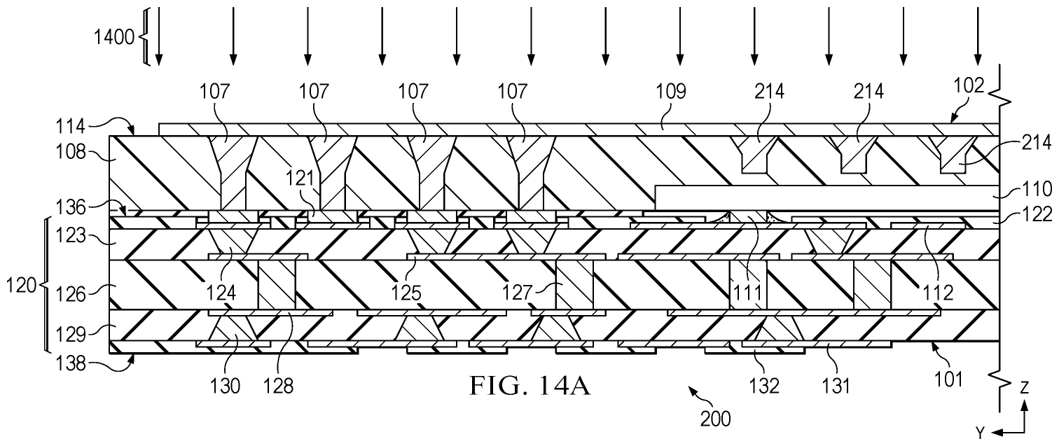

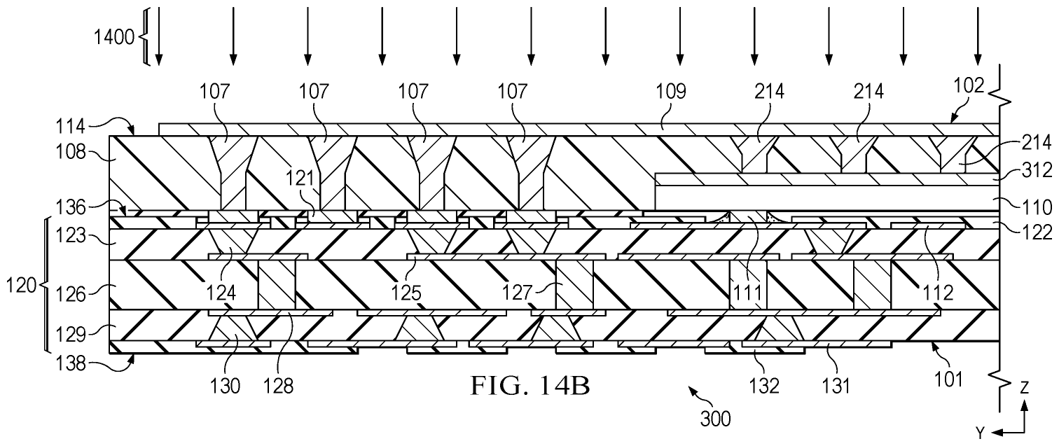

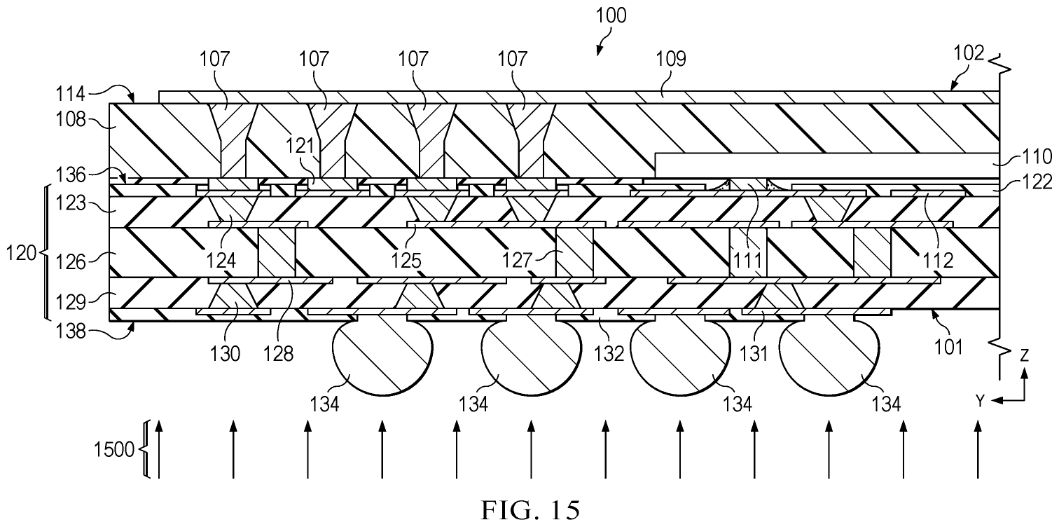

FIG. 14 shows one example of the shield formation at 414 during fabrication of the electronic device 100 of FIGS. 1-1B above. This example includes performing a deposition process 1400 (or continuing the previous deposition process 1300) that forms a metal shield 109 along the top package side 114 of the molded package structure 108 with the metal shield 109 contacting the tops of the conductive package vias 107. FIG. 14A shows another example during fabrication of the electronic device 200 that includes performing the deposition process 1400 (or continuing the via hole fill deposition process 1300) that forms the metal shield 109 along the top package side 114 of the molded package structure 108 with the metal shield 109 contacting the tops of the conductive package vias 107 and the tops of the second vias 214. FIG. 14B shows a further example during fabrication of the electronic device 300 that includes performing the deposition process 1400 (or continuing the via hole fill deposition process 1300) that forms the metal shield 109 along the top package side 114 of the molded package structure 108 with the metal shield 109 contacting the tops of the conductive package vias 107 and the tops of the second vias 214 to form a connection to the die shield 312.

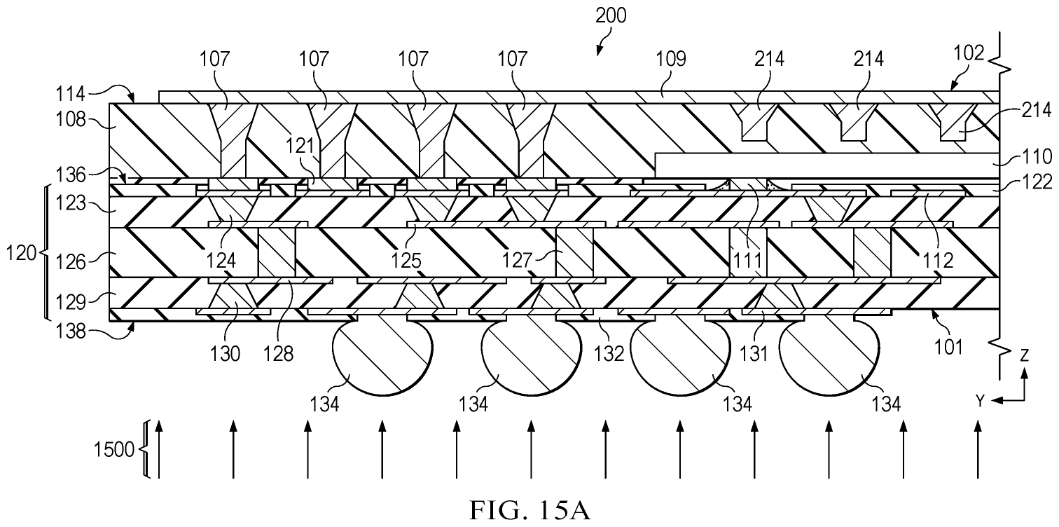

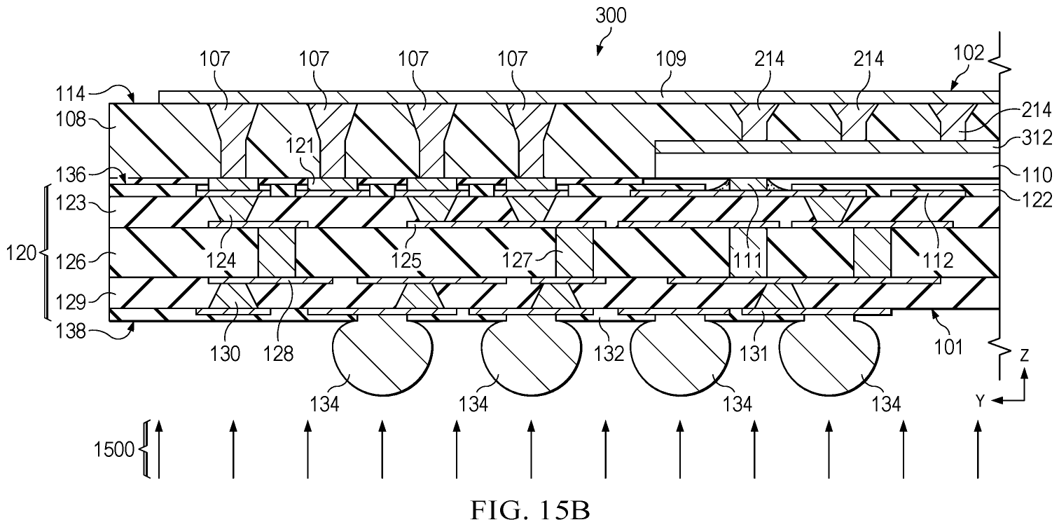

The method 400 continues at 415 in FIG. 4 with attaching solder balls to the bottom side of the multilevel package substrate. FIG. 15 shows one example during fabrication of the electronic device 100 of FIGS. 1-1B above, including performing a ball attach process 1500 that attaches the solder balls 134 to the second substrate side 138 of the multilevel package substrate 120 of FIG. 14. FIG. 15A shows another example of the ball attach processing at 415 in FIG. 4 during fabrication of the electronic device 200 of FIGS. 2-2B above. This example includes performing the ball attach process 1500 that attaches the solder balls 134 to the second substrate side 138 of the multilevel package substrate 120 of FIG. 14A. FIG. 15B shows another example of the ball attach processing at 415 in FIG. 4 during fabrication of the electronic device 300 of FIGS. 3-3B above. This example includes performing the ball attach process 1500 that attaches the solder balls 134 to the second substrate side 138 of the multilevel package substrate 120 of FIG. 14B.

In one example, the method 400 continues at 416 in FIG. 4 with package separation in the case where the previous processing at 402-414 is performed in a panel array. In this case, a laser cutting, etching, saw cutting or other separation process is performed as 416 that separates individual finished electronic devices (e.g., 100, 200, or 300) from the panel array structure. The finished and separated electronic devices can then be shipped or provided to a final device test process (not shown).

FIGS. 16 and 16A show top views of alternate examples in which the multilevel package substrate has elongated rectangular substrate pads to enhance thermal heat removal and facilitate improved shielding for EMI performance benefits. FIG. 16 shows a top view of another example multilevel package substrate 1620 of a prospective electronic device in a unit region of a panel array structure after a semiconductor die 1610 (e.g., optionally having a conductive back side shield 1612) has been flip chip attached to the top side of the multilevel package substrate 1620. The multilevel package substrate 1620 in this example has elongated rectangular conductive substrate pads silkscreened with conductive metallic paste 902 and a solder mask layer 1622 has openings spaced apart from the edges of the conductive substrate pads silkscreened with conductive metallic paste 902. FIG. 16A shows the unit area after molding (e.g., at 408 in FIG. 4 above) that forms a molded package structure 1608, via hole formation (e.g., at 410 and 411) by laser ablation, and deposition (e.g., at 412) of conductive metal in the rectangular and oval holes in the molding compound to form conductive first vias 1607 and conductive second vias 1614.

Modifications are possible in the described examples, and other implementations are possible, within the scope of the claims.

What is claimed is:

1. An electronic device, comprising:
a multilevel package substrate having opposite first and second substrate sides, first and second conductive pads spaced apart from one another along the first substrate side, and a conductive substrate terminal that is exposed along the second substrate side and is electrically coupled to the second conductive pad;
a semiconductor die attached to the first substrate side and having opposite first and second die sides, and a die terminal along the first die side, the die terminal electrically coupled to the first conductive pad; and
a molded package structure that encloses the semiconductor die and a portion of the first substrate side, the molded package structure having a package side, a metal shield along the package side, and a conductive package via that extends through the molded package structure and electrically couples the metal shield to the second conductive pad.

2. The electronic device of claim 1, wherein the molded package structure has a second conductive via that contacts the metal shield and extends into the molded package structure toward the second die side.

3. The electronic device of claim 2, wherein:
the semiconductor die has a second metal shield along the second die side; and
the second conductive via extends through the molded package structure and electrically couples the metal shield to the second metal shield.

4. The electronic device of claim 3, wherein the molded package structure has multiple instances of the second conductive via, each instance of the second conductive via extends through the molded package structure and electrically couples the metal shield to the second metal shield.

5. The electronic device of claim 4, wherein:
the multilevel package substrate has multiple instances of the second conductive pad;
each instance of the second conductive pad is electrically coupled to the conductive substrate terminal;
the molded package structure has multiple instances of the conductive package via; and
each instance of the conductive package via extends through the molded package structure and electrically couples the metal shield to the second conductive pad.

6. The electronic device of claim 2, wherein the second conductive via is spaced apart from the second die side.

7. The electronic device of claim 6, wherein:
the molded package structure has multiple instances of the second conductive via;
each instance of the second conductive via contacts the metal shield and extends into the molded package structure toward the second die side; and
each instance of the second conductive via is spaced apart from the second die side.

8. The electronic device of claim 7, wherein:
the multilevel package substrate has multiple instances of the second conductive pad;
each instance of the second conductive pad is electrically coupled to the conductive substrate terminal;
the molded package structure has multiple instances of the conductive package via; and
each instance of the conductive package via extends through the molded package structure and electrically couples the metal shield to the second conductive pad.

9. The electronic device of claim 2, wherein:
the multilevel package substrate has multiple instances of the second conductive pad;
each instance of the second conductive pad is electrically coupled to the conductive substrate terminal;
the molded package structure has multiple instances of the conductive package via; and
each instance of the conductive package via extends through the molded package structure and electrically couples the metal shield to the second conductive pad.

10. The electronic device of claim 1, wherein:
the multilevel package substrate has multiple instances of the second conductive pad;
each instance of the second conductive pad is electrically coupled to the conductive substrate terminal;
the molded package structure has multiple instances of the conductive package via; and
each instance of the conductive package via extends through the molded package structure and electrically couples the metal shield to the second conductive pad.

11. The electronic device of claim 10, wherein:
the electronic device has opposite bottom and top sides and four lateral sides;
the semiconductor die is spaced apart from the four lateral sides;
a first instance of the conductive package via is spaced apart from and between the semiconductor die and the first lateral side;
a second instance of the conductive package via is spaced apart from and between the semiconductor die and the second lateral side;
a third instance of the conductive package via is spaced apart from and between the semiconductor die and the third lateral side; and
a fourth instance of the conductive package via is spaced apart from and between the semiconductor die and the fourth lateral side.

12. The electronic device of claim 1, wherein the metal shield includes a ferrite metal material.

13. A method of fabricating an electronic device, the method comprising:
attaching a semiconductor die to a first substrate side of a multilevel package substrate with a die terminal of the semiconductor die electrically coupled to a first conductive pad of the multilevel package substrate;
forming a molded package structure over the semiconductor die and a portion of the first substrate side;
forming a hole through the molded package structure to expose a second conductive pad of the multilevel package substrate or a conductive material above the second conductive pad of the multilevel package substrate;
filling the hole with conductive material to form a conductive package via that extends through the molded package structure and contacts the second conductive pad or the conductive material above the second conductive pad; and
forming a metal shield along a package side of the molded package structure, the metal shield contacting the conductive package via.

14. The method of claim 13, further comprising:
forming a second hole into the molded package structure toward the second die side; and
filling the second hole with conductive material to form a second conductive via that extends into the molded package structure toward the second die side;
wherein the metal shield contacts the second conductive via.

15. The method of claim 14, further comprising forming a second metal shield along the second die side;
wherein:
forming the second hole exposes a portion of the second metal shield; and
filling the second hole with the conductive material forms the second conductive via that extends through the molded package structure and electrically couples the metal shield to the second metal shield.

16. The method of claim 14, wherein:
forming the second hole does not expose the second die side; and
filling the second hole with the conductive material forms the second conductive via that is spaced apart from the second die side.

17. The method of claim 14, wherein forming the hole and forming the second hole include performing a laser ablation process.

18. The method of claim 13, wherein forming the hole includes performing a laser ablation process.

19. The method of claim 14, further comprising, before forming the molded package structure, performing an attachment process that attaches a solder ball to the second conductive pad of the multilevel package substrate;
wherein:
forming the hole through the molded package structure exposes a portion of the solder ball; and
filling the hole with the conductive material forms the conductive package via that extends through the molded package structure and contacts the solder ball.

20. The method of claim 14, further comprising, before forming the molded package structure, performing a deposition process that deposits a conductive paste on the second conductive pad of the multilevel package substrate;
wherein:
forming the hole through the molded package structure exposes a portion of the conductive paste; and
filling the hole with the conductive material forms the conductive package via that extends through the molded package structure and contacts the conductive paste.
